(19) United States
(12) Patent Application Publication
(10) Pub. No.: US 2023/0137280 A1
(43) Pub. Date: May 4, 2023

(54) GAIN ATTENUATION CIRCUIT AND POWER AMPLIFIER INCLUDING THE SAME

(71) Applicant: SAMSUNG ELECTRO-MECHANICS CO., LTD., Suwon-si (KR)

(72) Inventors: Geunyong LEE, Suwon-si (KR); Hyunjin YOO, Suwon-si (KR)

(73) Assignee: SAMSUNG ELECTRO-MECHANICS CO., LTD., Suwon-si (KR)

(21) Appl. No.: 17/863,707

(22) Filed: Jul. 13, 2022

(30) Foreign Application Priority Data
Nov. 1, 2021 (KR) 10-2021-0147923

(51) Int. Cl. H03G 3/30; H03F 3/24

(52) U.S. Cl. CPC H03G 3/3042; H03F 3/245; H03F 2200/451; H03G 2201/103; H03G 2201/307

(57) ABSTRACT

A gain attenuation circuit that attenuates an input RF signal and transmits the attenuated RF signal to a power transistor is provided. The gain attenuation circuit includes a first diode connected between a first node positioned between a port to which the input RF signal is input and a control terminal of the power transistor, and a ground; a first transistor and a second transistor stacked between a first power source and the ground, and each including a diode-connection structure; and a third transistor configured to receive an operating voltage set by the first transistor and the second transistor through a control terminal, and operate the first diode based on the received operating voltage.

### CROSS-REFERENCE TO RELATED APPLICATION

This application claims the benefit under 35 USC §119(a) of Korean Patent Application No. 10-2021-0147923, filed on Nov. 1, 2021, in the Korean Intellectual Property Office on Nov. 01, 2021, the entire disclosure of which is incorporated herein by reference for all purposes.

### BACKGROUND

### 1. Field

The following description relates to a gain attenuation circuit and a power amplifier.

### 2. Description of Related Art

Wireless communication systems may adopt various digital modulation/demodulation methods based on the evolution of communication standards. An existing code division multiple access (CDMA) communication system may adopt a quadrature phase shift keying (QPSK) method, and wireless LAN according to the IEEE communication standard may adopt an orthogonal frequency division multiplexing (OFDM) method. Additionally, long term evolution (LTE) and LTE-Advanced, which are the latest standards of 3GPP, adopts QPSK, quadrature amplitude modulation (QAM), and OFDM schemes. These wireless communication standards implement a linear modulation scheme where it may be necessary that the magnitude or phase of a transmission signal be maintained during transmission.

A transmission device implemented in a wireless communication systems may include a power amplifier that amplifies a radio frequency (RF) signal to increase a transmission distance.

Accordingly, it may be beneficial for the power amplifier to amplify while maintaining linearity with respect to the magnitude and phase of the transmission signal.

The linearity means that the power of the output signal is constantly amplified according to the fluctuation of the input signal and the phase is maintained at the same time.

The output power of the power amplifier applied to the mobile device may be determined in consideration of cell coverage, and a power gain may be determined according to the specification of a transceiver positioned at a previous stage of the power amplifier. When high output power is necessary, a power amplifier having a high power gain is desired, and when low output power is necessary, a power amplifier having a low power gain is desired. Typically, the power gain may be adjusted by a power source voltage, and a bias current of the power amplifier. However, depending on the specifications of the transceiver, a gain attenuation circuit that attenuates the power gain may be desirable. That is, the magnitude range of the input RF signal input from the transceiver to the power amplifier may vary according to specifications of a transistor, and accordingly, the power amplifier may desire a gain attenuation circuit to attenuate the input RF signal.

The above information disclosed in this Background section is only for enhancement of understanding of the background of the invention, and therefore it may contain information that does not form the prior art that is already known in this country to a person of ordinary skill in the art.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

In a general aspect, a gain attenuation circuit includes a first diode connected between a first node positioned between a port to which an input radio frequency (RF) signal is input and a control terminal of a power transistor, and a ground; a first transistor and a second transistor stacked between a first power source and the ground; and a third transistor configured to receive an operating voltage set by the first transistor and the second transistor through a control terminal, and operate the first diode based on the received operating voltage.

Each of the first transistor and the second transistor may include a diode-connection structure.

The third transistor may be turned on, a current path may be formed to the third transistor, the first diode, and the ground, and a portion of the input RF signal may be bypassed to the ground by the current path.

An emitter of the third transistor may be connected to an anode of the first diode.

A control terminal of the first transistor and a collector of the first transistor may be connected to each other, and the collector of the first transistor may be connected to the first power source, and a control terminal of the second transistor and a collector of the second transistor may be connected to each other, and the collector of the second transistor may be connected to an emitter of the first transistor, and an emitter of the second transistor may be connected to the ground.

The operating voltage may be a voltage at the collector of the first transistor.

The circuit may include a first resistor connected between a cathode of the first diode and the ground; and a second resistor connected between the emitter of the second transistor and the ground.

The circuit may include a capacitor connected between the collector of the first transistor and the ground.

The circuit may include a first resistor and a first capacitor that are coupled in series between a collector of the third transistor and a bias circuit configured to supply a bias current to the power transistor.

A first portion of the input RF signal may be supplied to the bias circuit through the third transistor, the first resistor, and the first capacitor.

In a general aspect, a power amplifier includes a power transistor; a bias circuit configured to supply a bias current to a control terminal of the power transistor; and a gain attenuation circuit configured to attenuate an input radio frequency (RF) signal, wherein the gain attenuation circuit includes a first diode configured to bypass a portion of the input RF signal to a ground, a first transistor and a second transistor, configured to generate an operating voltage, and a third transistor configured to be turned on by the operating voltage, and configured to turn on the first diode.

The first transistor and the second transistor each include a diode-connection structure.

The third transistor may be turned on, a current path may be formed to a collector of the third transistor, an emitter of the third transistor, the first diode, and the ground, and a portion of the input RF signal is bypassed to the ground by the current path.

The operating voltage may be input to a base of the third transistor, a collector of the third transistor may be connected to a power source voltage, and an emitter of the third transistor may b connected to an anode of the first diode.

The first transistor and the second transistor may be stacked between a power source and the ground and the first transistor and the second transistor may be configured to generate the operating voltage which corresponds to a turn-on voltage.

The gain attenuation circuit may further include a first resistor connected between a cathode of the first diode and the ground; a second resistor connected between the first and second transistors and the ground; and a capacitor connected between a control terminal of the third transistor and the ground.

The gain attenuation circuit may further include a first resistor and a first capacitor that are coupled in series between a collector of the third transistor and the bias circuit.

A portion of the input RF signal may be input to the bias circuit through the third transistor, the first resistor, and the first capacitor.

Other features and aspects will be apparent from the following detailed description, the drawings, and the claims.

### BRIEF DESCRIPTION OF DRAWINGS

FIG. 1 illustrates an example power amplifier, in accordance with one or more embodiments.

FIG. 2 illustrates a circuit diagram of an example gain attenuation circuit, in accordance with one or more embodiments.

FIG. 3A illustrates a state of each element when the gain attenuation circuit operates, and FIG. 3B illustrates a state of each element when the gain attenuation circuit does not operate.

FIG. 4 illustrates a graph of a simulation result of a gain of the gain attenuation circuit.

FIG. 5 illustrates a circuit diagram of an example gain attenuation circuit, in accordance with one or more embodiments.

FIG. 6 illustrates a circuit diagram of an example gain attenuation circuit, in accordance with one or more embodiments.

FIG. 7 illustrates a simulation result with respect to an example power amplifier, in accordance with one or more embodiments.

Throughout the drawings and the detailed description, the same reference numerals refer to the same elements. The drawings may not be to scale, and the relative size, proportions, and depiction of elements in the drawings may be exaggerated for clarity, illustration, and convenience.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent after an understanding of the disclosure of this application. For example, the sequences of operations described herein are merely examples, and are not limited to those set forth herein, but may be changed as will be apparent after an understanding of the disclosure of this application, with the exception of operations necessarily occurring in a certain order. Also, descriptions of features that are known after an understanding of the disclosure of this application may be omitted for increased clarity and conciseness, noting that omissions of features and their descriptions are also not intended to be admissions of their general knowledge.

The features described herein may be embodied in different forms, and are not to be construed as being limited to the examples described herein. Rather, the examples described herein have been provided merely to illustrate some of the many possible ways of implementing the methods, apparatuses, and/or systems described herein that will be apparent after an understanding of the disclosure of this application.

Although terms such as “first,” “second,” and “third” may be used herein to describe various members, components, regions, layers, or sections, these members, components, regions, layers, or sections are not to be limited by these terms. Rather, these terms are only used to distinguish one member, component, region, layer, or section from another member, component, region, layer, or section. Thus, a first member, component, region, layer, or section referred to in examples described herein may also be referred to as a second member, component, region, layer, or section without departing from the teachings of the examples.

Throughout the specification, when an element, such as a layer, region, or substrate is described as being “on,” “connected to,” or “coupled to” another element, it may be directly “on,” “connected to,” or “coupled to” the other element, or there may be one or more other elements intervening therebetween. In contrast, when an element is described as being “directly on,” “directly connected to,” or “directly coupled to” another element, there can be no other elements intervening therebetween.

The terminology used herein is for the purpose of describing particular examples only, and is not to be used to limit the disclosure. As used herein, the singular forms “a,” “an,” and “the” are intended to include the plural forms as well, unless the context clearly indicates otherwise. As used herein, the term “and/or” includes any one and any combination of any two or more of the associated listed items. As used herein, the terms “include,” “comprise,” and “have” specify the presence of stated features, numbers, operations, elements, components, and/or combinations thereof, but do not preclude the presence or addition of one or more other features, numbers, operations, elements, components, and/or combinations thereof.

Unless otherwise defined, all terms, including technical and scientific terms, used herein have the same meaning as commonly understood by one of ordinary skill in the art to which this disclosure pertains and after an understanding of the disclosure of this application. Terms, such as those defined in commonly used dictionaries, are to be interpreted as having a meaning that is consistent with their meaning in the context of the relevant art and the disclosure of this application, and are not to be interpreted in an idealized or overly formal sense unless expressly so defined herein.

Also, in the description of example embodiments, detailed description of structures or functions that are thereby known after an understanding of the disclosure of the present application will be omitted when it is deemed that such description will cause ambiguous interpretation of the example embodiments.

Hereinafter, examples will be described in detail with reference to the accompanying drawings, and like reference numerals in the drawings refer to like elements throughout.

Throughout the specification, a radio frequency (RF) signal may a format of, but not limited to, Wi-Fi (IEEE 802.11 family, etc.), WiMAX (IEEE 802.16 family, etc.), IEEE 802.20, long term evolution (LTE), Evolution-Data Optimized (Ev-DO), high-speed packet access (HSPA), high-speed downlink packet access (HSDPA), high-speed uplink packet access (HSUPA), Enhanced Data GSM Evolution (EDGE), Global System for Mobile communication (GSM), Global Positioning System (GPS), General Packet Radio Service (GPRS), Code Division Multiple Access (CDMA), Time Division Multiple Access (TDMA), digital enhanced cordless communication (DECT), Bluetooth, third generation (3G), fourth generation (4G), fifth generation (5G), and any other wireless and wired protocols designated thereafter. However, the examples are not limited thereto.

Additionally, unless explicitly described to the contrary, the word “comprise”, and variations such as “comprises” or “comprising”, will be understood to imply the inclusion of stated elements but not the exclusion of any other elements.

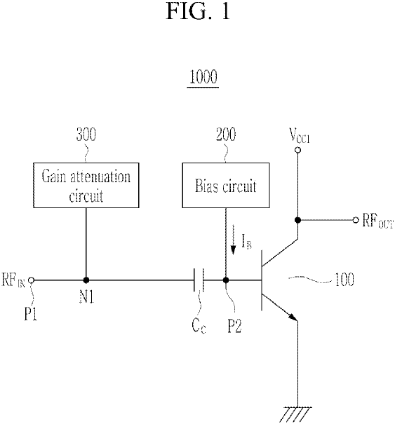

FIG. 1 illustrates an example power amplifier 1000, in accordance with one or more embodiments.

As illustrated in FIG. 1, an example power amplifier 1000, in accordance with one or more embodiments, may include a power transistor 100, a bias circuit 200, and a gain attenuation circuit 300.

An input RF signal RF_{IN} may be input to a first port P1, and may thereafter be input to a control terminal P2 of the power transistor 100 through a coupling capacitor Cc. In an example, the input RF signal RF_{IN} may be transmitted from a transceiver. The coupling capacitor Cc may remove a direct current (DC) from the received RF signal. Referring to FIG. 1, the control terminal of the power transistor 100 is illustrated as a second port P2.

The power transistor 100 may amplify a radio frequency (RF) signal input to the control terminal P2 and output the amplified RF signal RFₒᵤₜ to a first terminal. A first terminal of the power transistor 100 may be connected to a power source voltage V_{cc1}, and a second terminal of the power transistor 100 may be connected to a ground. As an example, the control terminal may be a base terminal, the first terminal may be a collector terminal, and the second terminal of the power transistor 100 may be an emitter terminal, respectively.

Referring to FIG. 1, a signal output from the power amplifier 1000 is illustrated as an output RF signal RF_{OUT}. In a non-limited example, the power transistor 100 may be implemented as various transistors such as a heterojunction bipolar transistor (HBT), a bipolar junction transistor (BJT), an insulated gate bipolar transistor (IGBT), and the like. Additionally, in FIG. 1, the power transistor 100 is illustrated as an N-type transistor, but may be replaced with a P-type transistor.

The bias circuit 200 may supply a bias current I_{B} that biases the power transistor 100 to the control terminal P2 of the power transistor 100. A bias level (bias point) of the power transistor 100 may be set through the bias current I_{B} provided from the bias circuit 200.

The gain attenuation circuit 300 may be connected to a node N1 positioned between the first port P1 and the second port P2, and may attenuate the input RF signal RF_{IN}. In an example, the gain attenuation circuit 300 may reduce an RF signal input to the second port P2 by bypassing some of the input RF signals RF_{IN} to the ground. That is, the magnitude of the RF signal in the second port P2 may be smaller than the magnitude of the RF signal in the first port P1 based on an operation of the gain attenuation circuit 300. In the power amplifier 1000, the magnitude range of the input signal that can be amplified may be determined based on an implementation, and the magnitude range of the input RF signal RF_{IN} may vary according to the specification of the transceiver.

Accordingly, the gain attenuation circuit 300, according to an example, may attenuate the magnitude range of the input RF signal RF_{IN} to a predetermined designed range. In an example, in order to prevent a DC signal generated from the gain attenuation circuit 300 from being input to the power transistor 100, the gain attenuation circuit 300 may be positioned in the previous stage of the coupling capacitor Cc. A specific configuration and operation of the gain attenuation circuit 300 will be described in more detail below.

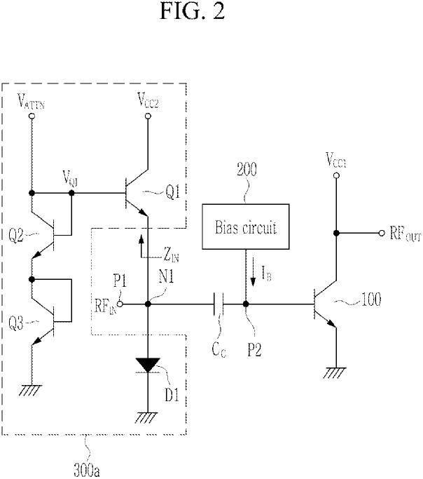

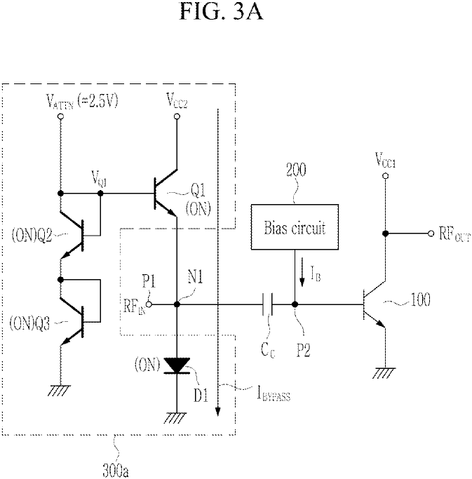

FIG. 2 illustrates a circuit diagram of a gain attenuation circuit 300a, in accordance with one or more embodiments.

As illustrated in FIG. 2, a gain attenuation circuit 300a, in accordance with one or more embodiments, may include a diode D1, a first transistor Q1, a second transistor Q2, and a third transistor Q3.

An anode of the diode D1 may be connected to the node N1, and a cathode of the diode D1 may be connected to the ground. When the diode D1 is turned on, some of an input RF signal RF_{IN} may be bypassed to the ground through the diode D1.

A first terminal (collector) of the first transistor Q1 may be connected to a power source voltage Vcc₂, and a second terminal (emitter) of the transistor Q1 may be connected to the node N1. That is, the second terminal (the emitter) of the transistor Q1 may be connected to the anode of the diode D1. The power source voltage VCC2 may be the same power source voltage as the power source voltage VCC1 or may be a power source voltage different from the power source voltage VCC1. In an example, the first terminal, the second terminal, and the control terminal of the transistor Q2 may respectively be a collector terminal, an emitter terminal, and a base terminal.

A base and a collector of the transistor Q3 may be connected to each other, and thus the transistor Q3 may have a diode-connection structure. An emitter of the transistor Q3 may be connected to the ground. A base and a collector of the transistor Q2 may be connected to each other, and thus the transistor Q3 may have a diode-connection structure. A collector and a base of the transistor Q2 may be connected to a power source voltage V_{ATTN}, and an emitter of the transistor Q2 may be connected to the collector and the base of the transistor Q3. That is, the transistor Q2 having the diode-connection structure and the transistor Q3 having the diode-connection structure may be stacked between the power source voltage V_{ATTN} and the ground. When the gain attenuation circuit 300 operates, the power source voltage V_{ATTN} may have a predetermined voltage. In a non-limiting example, the power source voltage V_{ATTN} may be 2.5 V. Additionally, when the gain attenuation circuit 300 does not operate, the power source voltage V_{ATTN} may have a predetermined voltage. In an example, the power source voltage V_{ATTN} may be 0 V. That is, the power source voltage V_{ATTN} may have two voltage levels (e.g., 2.5 V, 0 V) as a variable voltage.

Still referring to FIG. 2, a voltage at the contact point where the base of transistor Q2 and the collector are connected is indicated as an operating voltage V_{Q1.} The operating voltage V_{Q1}, may be determined by a turn-on voltage of the transistor Q2 and a turn-on voltage of the transistor Q3. The base and the collector of the transistor Q2 may be connected to the control terminal (base) of the transistor Q1, and the operating voltage V_{Q1}, is supplied to the control terminal of the transistor Q2. In an example, the transistor Q1 may be turned on by the operating voltage V_{Q1}, and as the transistor Q1 is turned on, the diode D1 may be turned on.

In the gain attenuation circuit 300a according to an example, the power source voltage V_{ATTN} may not be directly supplied to the control terminal of the transistor Q1, and the operating voltage V_{Q1} may be supplied to the control terminal of the transistor Q1 by the transistors Q2 and Q3. Accordingly, it is possible to prevent an overcurrent from flowing to the control terminal of the transistor Q1. A first portion of the current generated by the power source voltage V_{ATTN} may flow through the transistors Q2 and Q3, and a second portion of the current generated by the power source voltage V_{ATTN} may flow through the control terminal of the transistor Q1, and accordingly, an overcurrent inflow to the control terminal of transistor Q1 can be suppressed. In an example, the power source voltage V_{ATTN} may be implemented as a voltage source or a current source.

Referring to FIG. 2, equivalent impedance facing (visible) from the node N1 to the transistor Q1 (visible) is indicated by Z_{IN}. Since the node N1 is connected to a second terminal (e.g., the emitter) of the transistor Q1, the equivalent impedance Z_{IN} may have a very high value. Accordingly, it is possible to prevent the input RF signal RF_{IN} from escaping to the transistors Q2 and Q3 through the transistor Q1. That is, the input RF signal RF_{IN} may not unnecessarily escape to the transistor Q1 and the transistors Q2 and Q3. Additionally, only a part of the input RF signal RF_{IN} may be bypassed to the ground through the diode D1 in response to a predetermined value based on an implementation of the gain attenuation circuit 300a.

The transistors Q1, Q2, and Q3 may be implemented with various transistors such as a heterojunction bipolar transistor (HBT), a bipolar junction transistor (BJT), and an insulated gate bipolar transistor (IGBT). Additionally, in FIG. 2, the transistors Q1, Q2, and Q3 are indicated as N-type, but can be replaced with P-type.

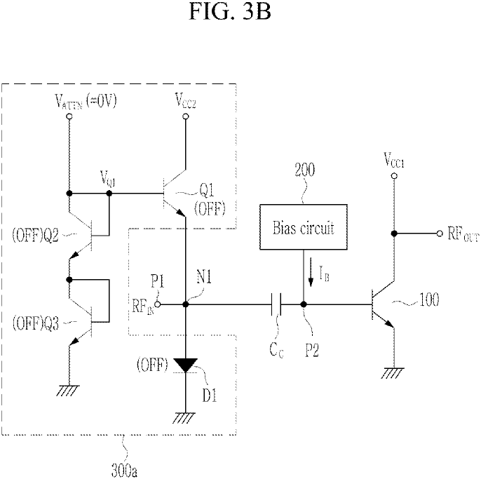

FIG. 3A illustrates a state of each element when the gain attenuation circuit 300a operates, and FIG. 3B illustrates a state of each element when the gain attenuation circuit 300a does not operate.

Referring to FIG. 3A, as an example, 2.5 V may be applied as the power source voltage V_{ATTN}. In this example, the transistor Q2 having the diode-connection structure and the transistor Q3 having the diode-connection structure are turned on. An operating voltage V_{Q1} determined by a turn-on voltage of the transistor Q2 and a turn-on voltage of the transistor Q3 are biased by the transistor Q1. Additionally, the transistor Q1 is turned on and the diode D1 is turned on. That is, a bypass current I_{BYPASS} is formed through the power source voltage V_{CC2}, the transistor Q1, and the diode D1. Some of the input RF signal RF_{IN} can be bypassed to the diode D1 and the ground by the bypass current I_{BYPASS}. As a part of the input RF signal RF_{IN} is bypassed, the RF signal input to the second port P2 may be attenuated.

Referring to FIG. 3B, as an example, 0 V may be applied as a value of the power source voltage V_{ATTN}. The transistor Q2 having the diode-connection structure and the transistor Q3 having the diode-connection structure are turned off.

Additionally, the transistor Q1 and the diode D1 are turned off. Accordingly, the bypass current I_{BYPASS} is not formed through the diode D1. That is, the input RF signal RF_{IN} may not be attenuated and transmitted to the second port P2.

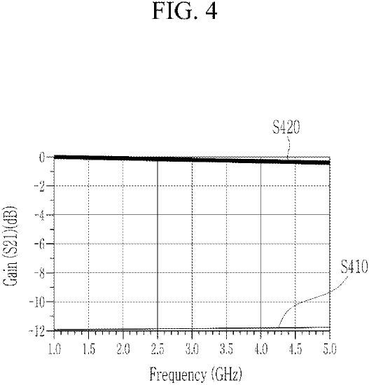

FIG. 4 is a graph illustrating a simulation result of a gain of the gain attenuation circuit 300a. Specifically, FIG. 4 illustrates a simulation result with respect to a parameter S21, which is a gain between the first port P1 and the second port P2.

In FIG. 4, the horizontal axis denotes a frequency and the vertical axis denotes a gain S21. Additionally, S410 indicates a gain S21 in an example where the power source voltage V_{ATTN} is 2.5 V, and S420 indicates a gain S21 in an example where the power source voltage V_{ATTN} is 0 V.

Referring to S410, when the gain attenuation circuit 300a operates, the gain S21 is near -12 dB.

That is, the RD signal in the second portion P2 may be attenuated by about 12 dB compared to the RF signal in the first portion P1. Referring to S420, when the gain attenuation circuit 300a does not operate, the gain S21 is near -0 dB. That is, the RF signal in the second port P2 may have substantially the same value as the RF signal in the first port P1.

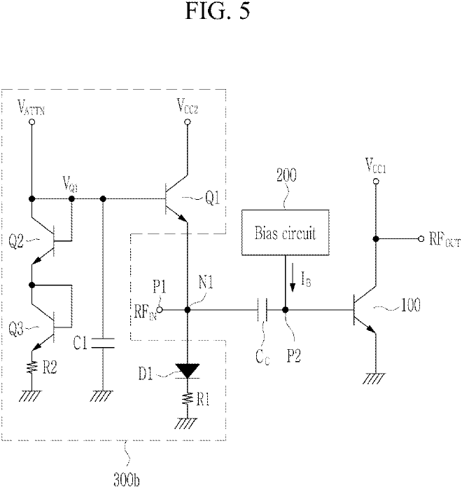

FIG. 5 illustrates an example circuit diagram indicating a gain attenuation circuit 300b, in accordance with one or more embodiments.

As illustrated in FIG. 5, a gain attenuation circuit 300b, in accordance with one or more embodiments, is similar to the gain attenuation circuit 200a of FIG. 2, except that a resistor R1, a resistor R2, and a capacitor C1 are added to the gain attenuation circuit 300a, and therefore a duplicated description will be omitted.

The resistor R1 may be connected between a diode D1 and the ground. The resistor R1 may control the amount of bypass current I_{BYPASS} described above. That is, the amount of the bypass current I_{BYPASS} can be adjusted according to a value of the resistor R1.

The resistor R2 may be connected between an emitter of a transistor Q3 and the ground. The resistor R2 controls the amount of current flowing to the ground through the transistor Q2 and the transistor Q3. That is, the amount of current flowing to the ground through the transistor Q2 having a diode-connection structure and the transistor Q3 having a diode-connection structure may be adjusted according to the value of the resistor R2.

The capacitor C1 may be connected between a control terminal of the transistor Q1 and the ground. The capacitor C1 may remove an AC component from an operating voltage V_{Q1}. That is, the capacitor C1 may prevent the AC component at the operating voltage V_{Q1} from being applied to the control terminal of the transistor Q1.

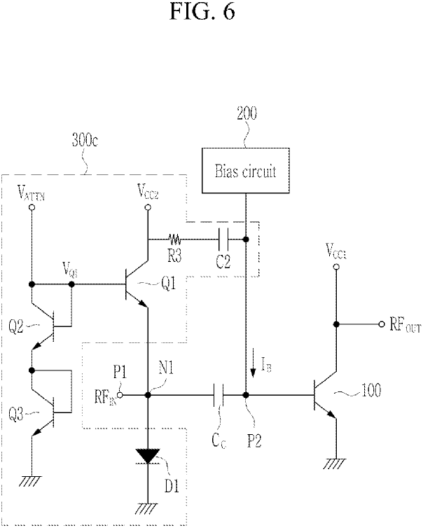

FIG. 6 is a circuit diagram of a gain attenuation circuit 300c, in accordance with one or more embodiments.

As illustrated in FIG. 6, a gain attenuation circuit 300c, in accordance with one or more embodiments, is similar to the gain attenuation circuit 300a of FIG. 2, except that a resistor R3 and a capacitor C2 are added to the gain attenuation circuit 300a, and therefore a duplicated description will be omitted.

A first end of the resistor R3 is connected to a first terminal of a transistor Q1, and a capacitor C2 may be connected between a second end of the resistor R3 and an output end of a bias circuit 200. That is, the resistor R3 and the capacitor C2 may be coupled in series between the first terminal of the transistor Q1 and the output terminal of the bias circuit 200. In an example, the output terminal of the bias circuit 200 means a terminal to which a bias current I_{B} is output. In an example, the positions of the resistor R3 and the capacitor C2 may be changed.

Additionally, the gain attenuation circuit 300c, in accordance with one or more embodiments, may further attenuate an input RF signal RF_{IN} through the resistor R3 and the capacitor C2, and may further improve the entire linearity of a power amplifier 1000. When the gain attenuation circuit 300c operates, some of the input RF signal RF_{IN} may be bypassed to the ground through a diode D1. Additionally, when the gain attenuation circuit 300c operates, a signal path may be formed to the bias circuit 200 through the resistor R3 and the capacitor C2. Accordingly, a part of the input RF signal RF_{IN} may be input to the bias circuit 200 via the transistor Q1, the resistor R3, and the capacitor C2. That is, since a part of the input RF signal RF_{IN} is also input to the bias circuit 200 through the transistor Q1, the resistor R3, and the capacitor C2, the gain attenuation circuit 300c may additionally attenuate the input RF signal RF_{IN}. In addition, since a part of the input RF signal RF_{IN} is input to the bias circuit 200, the linearity of the power amplifier 1000 can be improved. To improve linearity at high output power of the power amplifier 1000, a linearizer (not shown) is included in the bias circuit 200. Typically, the linearizer receives a part of the input RF signal RF_{IN} and may prevent deterioration of the base voltage of the power transistor 100. Accordingly, the gain attenuation circuit 300c according to an example may also provide a part of the input RF signal RF_{IN} to the bias circuit 200. The specific configuration and operation of the internal linearizer of the bias circuit 200 is known to a person of ordinary skill in the technical field to which the present invention belongs, and detailed description is omitted.

Like the gain attenuation circuit 300b of FIG. 5, the gain attenuation circuit 300c of FIG. 6 may further include a resistor R1, a resistor R2, and a capacitor C1.

Meanwhile, in FIG. 1 to FIG. 6, a single-ended power amplifier is described as the power amplifier, but the description with reference to FIG. 1 to FIG. 6 may equally applied to a differential power amplifier.

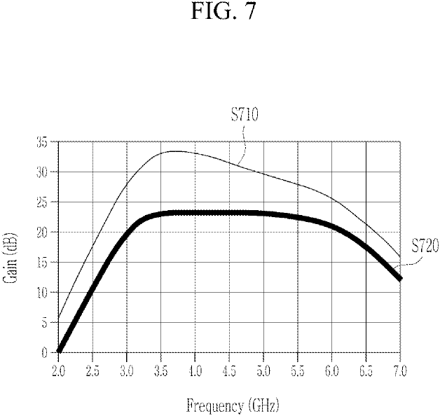

FIG. 7 illustrates a simulation result with respect to an example power amplifier. Specifically, a simulation result of FIG. 7 may indicate a gain in the example of applying the gain attenuation circuit 300c of FIG. 3 to a differential power amplifier.

In FIG. 7, the horizontal axis indicates a frequency, and the vertical axis indicates a gain. Additionally, S710 indicates a gain in the example that the gain attenuation circuit 300c does not operate, and S720 indicates a gain in the example that the gain attenuation circuit 300c operates. Referring to FIG. 7, in the case that the gain attenuation circuit 300c is applied and operates, the entire gain of the power amplifier can be effectively attenuated.

While this disclosure includes specific examples, it will be apparent after an understanding of the disclosure of this application that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents. Therefore, the scope of the disclosure is defined not by the detailed description, but by the claims and their equivalents, and all variations within the scope of the claims and their equivalents are to be construed as being included in the disclosure.

What is claimed is:

1. A gain attenuation circuit, comprising:
a first diode connected between a first node positioned between a port to which an input radio frequency (RF) signal is input and a control terminal of a power transistor, and a ground;
a first transistor and a second transistor stacked between a first power source and the ground; and
a third transistor configured to receive an operating voltage set by the first transistor and the second transistor through a control terminal, and operate the first diode based on the received operating voltage.

2. The circuit of claim 1, wherein each of the first transistor and the second transistor comprises a diode-connection structure.

3. The circuit of claim 1, wherein:
when the third transistor is turned on, a current path is formed to the third transistor, the first diode, and the ground, and
a portion of the input RF signal is bypassed to the ground by the current path.

4. The circuit of claim 1, wherein:
an emitter of the third transistor is connected to an anode of the first diode.

5. The circuit of claim 4, wherein:
a control terminal of the first transistor and a collector of the first transistor are connected to each other, and the collector of the first transistor is connected to the first power source, and
a control terminal of the second transistor and a collector of the second transistor are connected to each other, and the collector of the second transistor is connected to an emitter of the first transistor, and an emitter of the second transistor is connected to the ground.

6. The circuit of claim 5, wherein:
the operating voltage is a voltage at the collector of the first transistor.

7. The circuit of claim 5, further comprising:
a first resistor connected between a cathode of the first diode and the ground; and
a second resistor connected between the emitter of the second transistor and the ground.

8. The circuit of claim 7, further comprising:
a capacitor connected between the collector of the first transistor and the ground.

9. The circuit of claim 1, further comprising:
a first resistor and a first capacitor that are coupled in series between a collector of the third transistor and a bias circuit configured to supply a bias current to the power transistor.

10. The circuit of claim 9, wherein:
a first portion of the input RF signal is supplied to the bias circuit through the third transistor, the first resistor, and the first capacitor.

11. A power amplifier, comprising:
a power transistor;
a bias circuit configured to supply a bias current to a control terminal of the power transistor; and
a gain attenuation circuit configured to attenuate an input radio frequency (RF) signal,
wherein the gain attenuation circuit comprises:
a first diode configured to bypass a portion of the input RF signal to a ground,
a first transistor and a second transistor, configured to generate an operating voltage, and
a third transistor configured to be turned on by the operating voltage, and configured to turn on the first diode.

12. The power amplifier of claim 11, wherein the first transistor and the second transistor each comprise a diode-connection structure.

13. The power amplifier of claim 11, wherein:
when the third transistor is turned on, a current path is formed to a collector of the third transistor, an emitter of the third transistor, the first diode, and the ground, and
a portion of the input RF signal is bypassed to the ground by the current path.

14. The power amplifier of claim 11, wherein:
the operating voltage is input to a base of the third transistor, a collector of the third transistor is connected to a power source voltage, and an emitter of the third transistor is connected to an anode of the first diode.

15. The power amplifier of claim 11, wherein:
the first transistor and the second transistor are stacked between a power source and the ground and the first transistor and the second transistor are configured to generate the operating voltage which corresponds to a turn-on voltage.

16. The power amplifier of claim 15, wherein:
the gain attenuation circuit further comprises:
a first resistor connected between a cathode of the first diode and the ground;
a second resistor connected between the first and second transistors and the ground; and
a capacitor connected between a control terminal of the third transistor and the ground.

17. The power amplifier of claim 11, wherein:
the gain attenuation circuit further comprises a first resistor and a first capacitor that are coupled in series between a collector of the third transistor and the bias circuit.

18. The power amplifier of claim 17, wherein:
a portion of the input RF signal is input to the bias circuit through the third transistor, the first resistor, and the first capacitor.
